(19) United States
(12) Patent Application Publication
(10) Pub. No.: US 2013/0265728 A1
(43) Pub. Date: Oct. 10, 2013

(54) ELECTRONIC CONTROL UNIT

(71) Applicant: DENSO CORPORATION, Kariya-city (JP)

(72) Inventor: Katsuhiro Sakai, Inazawa-city (JP)

(73) Assignee: Denso Corporation, Kariya-city (JP)

(21) Appl. No.: 13/855,922

(22) Filed: Apr. 3, 2013

(30) Foreign Application Priority Data
Apr. 6, 2012 (JP) 2012-087535

(51) Int. Cl. H05K 5/00

(52) U.S. Cl. CPC H05K 5/0078
USPC 361/752

(57) ABSTRACT

The electronic control unit comprises (i) a circuit board including an electronic part, (ii) a connector mounted on the circuit board and (iii) a housing with storage space. The connector electrically connects the circuit board with an external equipment. The housing includes the circuit board and a part of the connector. The housing has an opening to expose a tip of the connector outward. The housing includes a wet inhibition portion which prevents a water drop falling on the top plate of the housing from flowing toward the connector.

### CROSS REFERENCE TO RELATED APPLICATION

This application is based on Japanese Patent Application No. 2012-87535 filed on Apr. 6, 2012, the disclosure of which is incorporated herein by reference.

### TECHNICAL FIELD

The present disclosure relates to a drip-proof structure of an electronic control unit.

### BACKGROUND

Recently more and more electronic control units (ECUs) are mounted on a vehicle as electronic control of the vehicle is advanced. One of the many electronic control units is, for example, an airbag ECU.

The airbag ECU makes a determination of a collision to the vehicle and conducts an airbag deployment control based on a detection result of a sensor located inside of the airbag ECU. The airbag ECU is located on a floor near the foot of a front seat at the center of a vehicle width direction in order to detect the collision from a front and additionally from a side of the vehicle. An air-conditioner is also located at the center of the vehicle width direction of the front seat. The air-conditioner is often located above the airbag ECU.

A water drop may be generated by condensation of the air-conditioner. In a case where the water drop falls on a housing of the airbag ECU, there is a possibility that the water drop may invade the inside of the airbag ECU from a gap between the housing and a connector. It is concerned that in a case where the water drop invading into the inside splashes on a connector terminal or a circuit board, a short circuit may be occurred in a circuit. Therefore, it is required that a drip-proof structure be provided in the airbag ECU against such as the condensation of the air-conditioner.

For example, JP-A-2008-130359 discloses that a drip-proof eave is arranged above a housing gap, a connector and the like. There is a disclosure in which a sheet is pasted on the upper surface of the housing.

In an electronic control unit in the above described disclosures, the drip-proof structure by the drip-proof eave or the sheet is located above the connector. Thus, a person has to work with putting into his or her hand below the drip-proof structure when a wire harness is assembled with the connector. A working efficiency of an assembly is decreased.

Additionally, because an upside of the connector is covered, it is not able to assemble as watching a joint of the connector. Therefore, it is difficult to check a fitting between the connector and the wire harness.

### SUMMARY

It is an object of the present disclosure to provide an electronic control unit which prevents invasion of a water drop without decreasing a working efficiency of an assembly to a connector.

The electronic control unit comprises (i) a circuit board on which an electronic part is mounted, (ii) a connector mounted on circuit board, and (iii) a housing defining a storage space. The connector electrically connects the circuit board with an external equipment. The housing stores the circuit board and part of the connector. The housing also has an opening to expose a tip of the connector to an outside of the housing. The housing includes a top plate and a wet inhibition portion which prevents a water drop falling on the top plate of the housing from flowing toward the connector.

According to the above electronic control unit, it becomes possible that the water drop is prevented from invading into the inside of electronic control unit without decreasing a working efficiency of the assembly.

### BRIEF DESCRIPTION OF THE DRAWINGS

The above and other objects, features and advantages of the present disclosure will become more apparent from the following detailed description made with reference to the accompanying drawings. In the drawings:

FIG. 1 is an overall exploded view illustrating an airbag ECU in the present disclosure;

FIG. 2 is a perspective view illustrating a housing in a first embodiment;

FIG. 3 is a perspective view illustrating a housing in a first modification of the first embodiment;

FIG. 4 is a perspective view illustrating a housing in a second modification of the first embodiment;

FIG. 5 is a perspective view illustrating a housing in a third modification of the first embodiment;

FIG. 6 is a perspective view illustrating a housing in a second embodiment;

FIG. 7 is a perspective view illustrating a housing in a first modification of the second embodiment;

FIG. 8A is a perspective view illustrating a housing in a second modification of the second embodiment;

FIG. 8B is a right side view illustrating a housing in a second modification of the second embodiment;

FIG. 9 is a perspective view illustrating a housing in a third embodiment;

FIG. 10 is a perspective view illustrating a housing in a fourth embodiment;

FIG. 11 is a perspective view illustrating a housing in a first modification of the fourth embodiment;

FIG. 12 is a perspective view illustrating a housing in a second modification of the fourth embodiment; and

FIG. 13 is a perspective view illustrating a housing in a fifth embodiment.

### DETAILED DESCRIPTION

As follows, electronic control units in embodiments of the present disclosure will be described with reference to drawings. An airbag ECU 1 in embodiments is an example of the electronic control unit. The airbag ECU is equipped in a vehicle and conducts an airbag deployment control. The airbag ECU makes a determination of a collision to the vehicle based on a detection result which is outputted from a sensor.

### First Embodiment

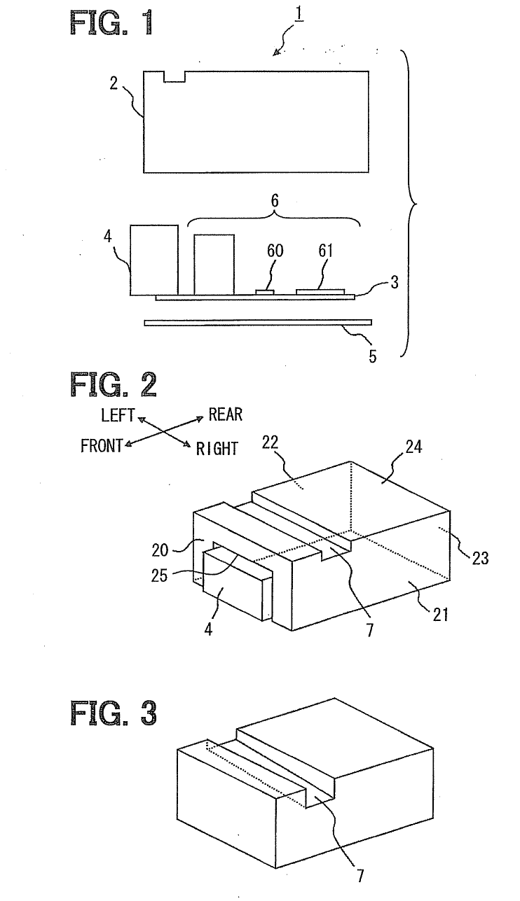

A structure of the airbag ECU 1 will be described with reference to FIG. 1.

FIG. 1 describes an overall view of the airbag ECU 1.

As described in FIG. 1, the airbag ECU 1 includes a housing 2, a circuit board 3, a connector 4, and a stationary portion 5.

As described in FIG. 2, in the present embodiment, the housing 2 integrally includes a front sidewall 20, a right sidewall 21, a left sidewall 22, a rear sidewall 23, and the top plate 24. The right sidewall 21 is adjacent to the right of the front sidewall 20. The left sidewall 22 is adjacent to the left of the front sidewall 20. The rear sidewall 23 faces to the front sidewall 20. The top plate 24 is at top faces of the four sidewalls. The housing 2 is a substantially box-shaped storage part, being made of metal or resin. The front sidewall 20 has an opening 25, which is used to arrange a connector 4 described below.

A direction of the opening 25, i.e., a direction from the rear sidewall 23 to the front sidewall 20, is denoted as a front direction and an opposite direction to the front direction is denoted as a rear direction. A right direction perpendicular to the front direction and parallel to a top plate 24 is denoted as a right direction and an opposite direction to the right direction is denoted as a left direction. Therefore, a right-and-left direction in the present embodiment can correspond to a width direction.

The front sidewall 20 in the present embodiment can correspond to an example of a first sidewall. The right sidewall 21 and the left sidewall 22 can correspond to an example of a second sidewall and a third sidewall respectively.

The housing 2 stores the circuit board 3 and a part of the connector 4. An electronic part 6 is mounted on the circuit board 3. The electronic part 6 includes an acceleration sensor 60, a microcomputer 61 and the like in order to detect the collision to the vehicle. The connector 4 is connected with the circuit board 3. A tip of the connector 4 protrudes outward from the opening 25 of the housing 2. The circuit board 3 is arranged on and fixed to the stationary portion 5 by an attachment portion (not shown) such as a screw.

The airbag ECU 1 of the first embodiment will be more specifically described with reference to FIG. 2. FIG. 2 is a perspective view illustrating the housing 2 in the first embodiment.

As described in FIG. 2, in the first embodiment, a groove portion 7 is formed to entirely extend across the top plate 24 in a width direction of the top plate 24, where the width direction coincides with the right direction and the left direction as illustrated in FIG. 2. In the first embodiment, in a case where a water drop is dropped on the top plate 24 and the airbag ECU is inclined in response to traveling a slope road and the like so that the water drop flows toward a connector 4, the water drop is flowed and dropped to the groove portion 7. The water drop dropped in the groove portion 7 is guided to both ends of the top plate 24, and thereafter dropped to the right sidewall 21 and/or the left sidewall 22.

The groove portion 7 can correspond to an example of wet inhibition portions and also correspond to an example of wet inhibition means.

According to the airbag ECU 1 in the first embodiment, the water drop is dropped to the groove portion 7 and thereafter dropped to the right sidewall 21 and/or the left sidewall 22. It is possible to prevent the water drop from flowing toward the connector 4. Therefore, it is prevented that the water drop invades from a gap between the housing 2 and the connector 4.

As a first modification of the first embodiment, as described in FIG. 3, the bottom of the groove portion 7 may be sloped toward the right sidewall 21. In the first modification, in a case where the water drop is dropped to the groove portion 7, the water drop is positively dropped to the sloped side (in this example, to the right sidewall 21). In a case where the bottom of the groove portion 7 is sloped, toward the left sidewall 22, the same effect as when the bottom of the groove portion 7 is sloped toward the right sidewall 21 can be obtained.

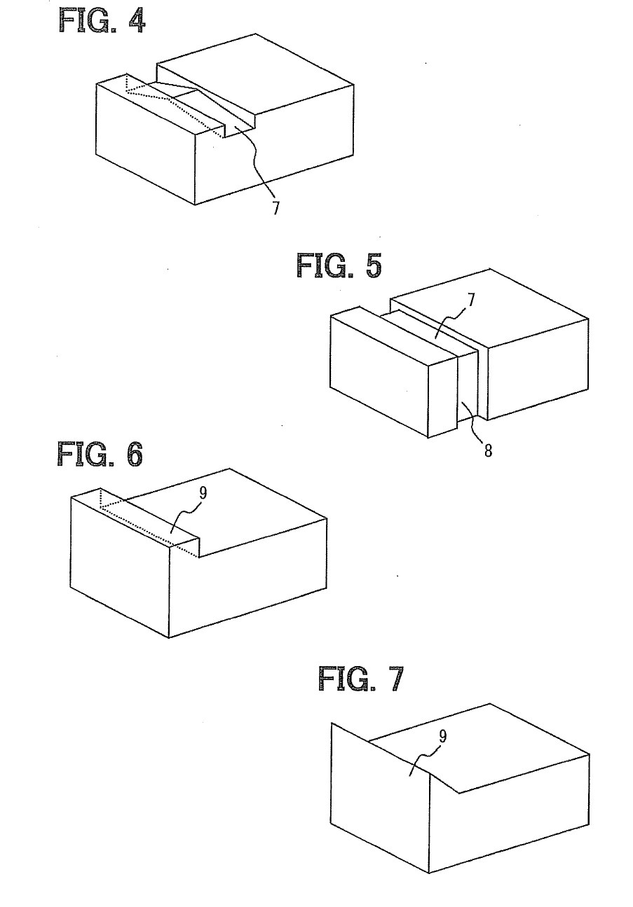

As a second modification of the first embodiment, as described in FIG. 4, the bottom of the groove portion 7 may includes two slopes. The bottom of the groove portion 7 may be sloped toward both the right sidewall 21 and the left sidewall 22 from a substantial center of the bottom. According to the second modification, in a case where the water drop is dropped to the groove portion 7, the water drop is dropped to both the right sidewall 21 and/or the left sidewall 22 positively and equally. Each of the two slopes of the bottom of the groove portion 7 has a slope angle enough for a water drop to fall. The second modification can ensure a larger inner space of the housing 2 than the first modification of the first embodiment.

As a third modification of the first embodiment, as described in FIG. 5, a let-out groove 8 connected with the groove portion 7 may be provided in each of the right sidewall 21 and the left sidewall 22 of the housing 2. According to the third modification, the let-out groove 8 is integrally provided with the groove portion 7. That is, the let-out groove 8 is continuously connected with the groove portion 7. The water drop dropped to the groove portion 7 is guided to both ends of the top plate 24. The water drop flows into the let-out groove 8 and is guided to a bottom erid of the right sidewall 21 and/or the left sidewall 22. Therefore, the water drop dropped to the right sidewall 21 and/or the left sidewall 22 is prevented from going around toward the connector 4.

### Second Embodiment

A second embodiment will be described with reference to FIG. 6. FIG. 6 shows a perspective view illustrating a housing 2 in the second embodiment.

As described in FIG. 6, at an edge of the front sidewall 20, a dam portion 9 is formed to entirely extend across the top plate 24 in the width direction of the top plate 24. The dam portion 9 is an alternative to the groove portion 7 in the first embodiment According to the second embodiment, in a case where the water drop falling on the top plate 24 flows toward the connector 4, the water drop is dammed by the dam portion 9. The dammed water drop is guided to the both ends of the top plate 24 provided with the dam portion 9. The dammed water drop is dropped to the right sidewall 21 and/or the left sidewall 22. Because the other element of the second embodiment is similar to that of the first embodiment, its explanation may be omitted.

The groove portion 7 can correspond to an example of wet inhibition portions and also can correspond to an example of wet inhibition means.

According to the above airbag ECU 1 in the second embodiment, the water drop is dammed by the dam portion 9 and is dropped to the right sidewall 21 and/or the left sidewall 22 of the housing 2, so that the water drop is prevented from flowing toward the connector 4. Therefore, the water drop is prevented from invading from the gap between the housing 2 and the connector 4. Moreover, the technical effect of the dam portion 9 can be maximized, because the dam portion 9 is provided at the edge of the front sidewall 20 and the water drop is dammed just before the connector 4.

As a first modification of the second embodiment, as described in FIG. 7, a top face of the dam portion 9 may be sloped down toward the top plate 24, which is behind the dam portion 9. In the first modification, in a case where the water drop falls on the top face of the dam portion 9, the water drop flows down to the top plate 24 in accordance with a slope of the top face of the dam portion 9. Thus, the water drop flows toward an opposite side of the top plate 24 from the connector 4. Therefore it is possible to prevent the water drop from flowing toward the connector 4.

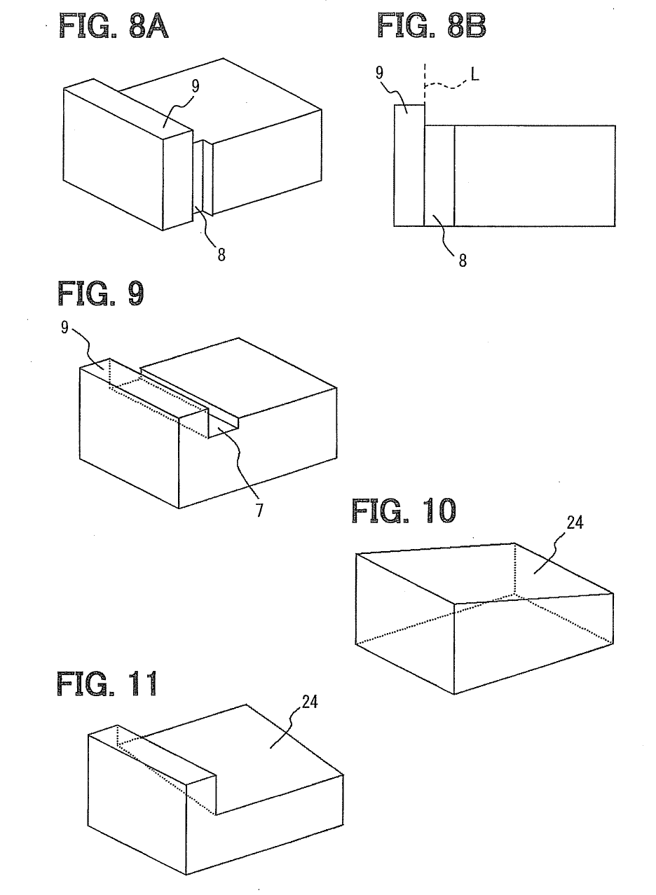

As a second modification of the second embodiment, as described in FIG. 8A and FIG. 8B, the housing 2 may have the let-out groove 8 at a predetermined portion of each of the right sidewall 21 and the left sidewall 22. The predetermined portion is a portion along an extended line L of a rear wall of the dam portion 9. In the second modification, the water drop is dammed by the dam portion 9 and guided to each of the both ends of the top plate 24. The water drop flows into the let-out groove 8 provided on the extended line L extended from the rear wall of the dam portion 9. The let-out groove 8 guides the water drop to the bottom end of the right sidewall 21 and/or the left sidewall 22. It is possible to prevent the water drop dropped to the right sidewall 21 and/or the left sidewall 22 from going around to the connector 4.

### Third Embodiment

A third embodiment will be described with reference to FIG. 9. FIG. 9 shows a perspective view illustrating a housing 2 in the third embodiment.

As described in FIG. 9, in the third embodiment, the groove portion 7 in the first embodiment and the dam portion 9 in the second embodiment are provided on the top plate 24. The dam portion 9 is provided before the groove portion 7. The rear wall of the dam portion 9 serves as one side of the groove portion 7. In the third embodiment, in a case where the amount of the water drop which falls down in the groove portion 7 is more than the volume of the groove portion 7 and the water drop overflows from the groove portion 7, the water drop is dammed by the dam portion 9.

According to the above airbag ECU 1 in the third embodiment, the water drop which overflows from the groove portion 7 is dammed by the dam portion 9 which is nearer the connector 4 than the groove portion 7 is. The water drop is prevented from flowing toward the connector 4. Therefore, it is prevented that the water drop invades from the gap between the housing 2 and the connector 4. Additionally, because the rear wall of the dam portion 9 serves as a front face of the groove portion 7, the dam portion 9 is integrated with the groove portion 7 so that a structure of a mold of the housing 2 can be simplified. Therefore, the groove portion 7 and the dam portion 9 of the top plate 24 are produced easily.

### Fourth Embodiment

A fourth embodiment will be described with reference to FIG. 10. FIG. 10 shows a perspective view illustrating a housing 2 in the fourth embodiment.

As described in FIG. 10, in the fourth embodiment, the top plate 24 is sloped down toward the rear sidewall 23. According to this structure, in a case where the water drop falls on the top plate 24, the water drop is dropped to the rear sidewall 23, that is, the water drop is dropped to an opposite side of the housing 2 from the connector 4.

According to the above airbag ECU 1 in the fourth embodiment, because of the inclination of the top plate 24 itself, the water drop falling on the top plate 24 is flowed along a slope of the top plate 24. According to this structure, the water drop on the top plate 24 is more surely removed so that the water drop is prevented from flowing toward the connector 4. Thus, it is prevented that the water drop invades from the gap between the housing 2 and the connector 4.

As a first modification of the fourth embodiment, as described in FIG. 11, the top plate 24 may be sloped toward the right sidewall 21. In the first modification, in a case where the water drop falls on the top plate 24, the water drop is positively dropped toward a sloped side (the right sidewall 21 in the above case). In a case where the top plate 24 is sloped toward the left sidewall 22, the same technical effect as when the top plate 24 is sloped toward the right sidewall 21 can be obtained.

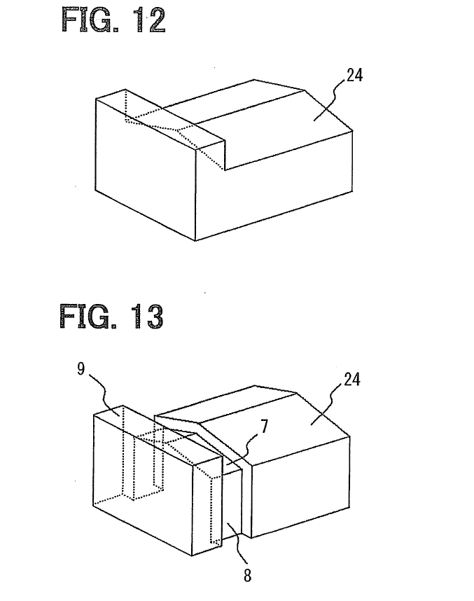

As a second modification of the fourth embodiment, as described in FIG. 12, the top plate 24 may include two slopes. A first slope of the top plate 24 is sloped down toward the right sidewall 21 from the substantial center of the top plate 24. A second slope of the top plate 24 is sloped down toward the left sidewall 22 from the substantial center of the top plate 24. According to the second modification, in a case where the water drop falls on the top plate 24, it is possible that the water drop is dropped to the right sidewall 21 and/or the left sidewall 22 positively and equally. The slopes of the top plate 24 have a slope angle enough for a water drop to fall. The housing 2 in the second modification of the fourth embodiment can make thinner in a vertical direction than the first modification of the fourth embodiment.

### Fifth Embodiment

A fifth embodiment will be described with reference to FIG. 13. FIG. 13 shows a perspective view illustrating a housing 2 in the fifth embodiment.

As described in FIG. 13, the housing 2 in the fifth embodiment includes the groove portion 7, the let-out groove 8, the dam portion 9, and the top plate 24. According to the fifth embodiment, in a case where the water drop falls on the top plate 24, the water drop is dropped to the right sidewall 21 and/or the left sidewall 22 in accordance with the slope of the top plate 24. If the water drop flows toward the connector 4, the water drop is dropped to the groove portion 7 and then to be dropped to the right sidewall 21 and/or the left sidewall 22 in accordance with the slope of the bottom of the groove portion 7. Furthermore, in a case where the water drop overflows from the groove portion 7 because of a lot of water drop, the water drop can be dammed by the dam portion 9. Additionally, after the water drop is dropped to the right sidewall 21 and/or the left sidewall 22, the water drop is guided to bottom ends of the right sidewall 21 and/or the left sidewall 22 by the let-out groove 8. It is possible to prevent the water drop from going around to the connector 4.

As described above, according to the airbag ECU 1 in the fifth embodiment, because the housing 2 is prepared for every conceivable case of the flow of the water drop, the water drop is more surely prevented from flowing toward the connector 4. Therefore, the water drop is prevented from invading into the inside of the air bag ECU from the gap between the housing 2 and the connector 4.

As described in the fifth embodiment, it is noted that embodiments can be combined and/or variations may be made within a spirit and scope of the present disclosure..

In the above each embodiment, although the airbag ECU is described as an example of electronic control units, the electronic control unit is not limited to the airbag ECU. The above-described structures are applicable to various kinds of electronic control units, for example the engine ECU and the like.

Summarizing the above embodiment, an electronic control unit comprises (i) a circuit board 3 on which an electronic part 6 is mounted, (ii) a connector 4 mounted on circuit board 3, and (iii) a housing 2 defining a storage space. The connector 4 electrically connects the circuit board 3 with an external equipment. The housing 2 stores the circuit board 3 and a part of the connector 4. The housing 2 also has an opening 25 to expose a tip of the connector 4 to an outside of the housing 2. The housing 2 includes a top plate 24 and a wet inhibition portion which prevents a water drop falling on the top plate 24 of the housing 2 from flowing toward the connector 4.

According to the structure, the water drop falling on the top plate 24 is prevented from flowing toward the connector 4 by wet inhibition portions. It is possible to prevent that the water drop invades from a gap between the housing 2 and the connector 4.

The opening 25 may be formed in the front sidewall 20 of the housing 2.

According to the structure, because the tip of the connector 4 protrudes outward from the opening 25 of the housing 2, it is able to ensure a space for locating apparatus, such as the air-conditioner, which are mounted above the housing 2, i.e. the electronic control unit.

The wet inhibition portion may include a groove portion 7 provided on the top plate 24.

According to the structure, if the water drop falling on the top plate 24 flows toward the connector 4, the amount of water flowing toward the connector 4 can be reduced because the water drop is dropped to the groove portion 7.

The groove portion 7 may entirely extend across the top plate 24 in width direction of the top plate 24.

According to the structure, the water drop falling on the top plate 24 is guided to both ends of the width direction of the top plate 24 and thereafter dropped to the right sidewall 21 and/or the left sidewall 22. Therefore, it is possible that the water drop collected on the groove portion 7 is more surely removed from the top plate 24 of the housing 2.

The wet inhibition portion includes a dam portion 9 which protrudes upward on the top plate 24.

According to the structure, if the water drop falling on the top plate 24 flows toward the connector 4, the amount of water flowing toward the connector 4 can be reduced because the water drop is dammed by the dam portion 9.

A top face of the dam portion 9 may be sloped downward toward the top plate 24. The top plate 24 is on an opposite side of the dam portion 9 from the connector 4.

According to the structure, the water drop falling on the top face of the dam portion 9 flows down along a slope of the top face of the, dam portion 9 to the top plate. Therefore, it is possible to prevent the water drop from flowing toward the connector 4.

The dam portion 9 may be provided on one of edges of the top plate 24. The one of edges is nearest to the opening 25 of the top plate 24 among the edges of the top plate 24.

According to the structure, it is possible to maximize the technical effect of the dam portion 9. The technical effect includes such that the water drop is prevented from flowing toward the connector.

The dam portion 9 may entirely extend across the top plate 24 in a width direction of the top plate 24.

According to the structure, the water drop dammed by the dam portion 9 is guided to the both ends of the width direction of the top plate 24 and thereafter dropped to the right sidewall 21 and/or the left sidewall 22. Therefore, it is possible that the water drop dammed by the dam portion 9 is more surely removed from the top plate 24 of the housing 2.

The dam portion 9 has a front wall and a rear wall. The rear wall of the dam portion 9 is farther from the opening 25 of the housing 2 than the front wall of the dam portion 9 is. A groove portion 7 may be provided on the top plate 24 along the rear wall of the dam portion 9.

According to the structure, in a case where a mount of water drop falling down to the groove portion 7 is more than the volume of the groove portion 7, it is possible to dam the water drop overflowing from the groove portion 7.

The rear wall of the dam portion 9 may serve as a sidewall of the groove portion 7.

According to the structure, a mold of the housing 2 can be simplified and it is possible that the groove portion 7 and the dam portion 9 of the top plate 24 are easily produced.

In addition to the front sidewall 20 of the housing 2, the housing 2 further has a right sidewall 21 and a left sidewalls 22 opposite to each other.

A bottom of the groove portion 7 is sloped toward one of the right sidewall 21 and the left sidewalls 22 of the housing 2.

According to the structure, it is possible to drop the water drop which is dropped to the groove portion 7 toward the right sidewall 21 and/or the left sidewall 22 in accordance with a slope of the groove portion 7.

The bottom of the groove portion 7 may be sloped downward toward the right sidewall 21 and the left sidewalls 22 of the housing 2 from a substantial center of the groove portion 7.

According to the structure, it is possible to equally drop the water drop which is dropped to the groove portion 7 to the right sidewall 21 and/or the left sidewall 22 in accordance with each of the two slopes of the bottom of the groove portion 7. Each of the two slopes has a slope angle enough for a water drop to fall and therefor an inner space of the housing 2 can be ensured.

The top plate 24 may be sloped toward an opposite side of the top plate 24 from the connector 4.

According to the structure, it is able to cause the water drop falling on the top plate to flow the opposite side of the top plate 24 from of the connector 4.

The housing 2 has a right sidewall 21 and a left sidewalls 22 which are opposite to each other. The top plate 24 may be sloped toward at least one of the right sidewall 21 and the left sidewalls 22 of the housing 2.

According to the structure, it is possible to drop the water drop falling on the top plate 24 toward the right sidewall 21 and/or the left sidewall 22 in accordance with a slope of the top plate 24.

The top plate 24 may be provided with a first slope and a second slope. The first slope is sloped downward toward one of the right sidewall 21 and the left sidewalls 22 from a substantial center of the top plate 24 and the second slope is sloped downward toward the other of the right sidewall 21 and the left sidewall 22 from the substantial center of the top plate 24.

According to the structure, it is possible to equally drop the water drop falling on the top plate 24 toward the right sidewall 21 and/or the left sidewall 22 in accordance with each of the first slope and the second slope of the top plate 24. Each of the first slope and the second slope has a slope angle enough for a water drop to fall. The housing can make thinner in a vertical direction.

A let-out groove 8 connected with the groove portion 7 may be provided on each of the right sidewall 21 and the left sidewalls 22 of the housing 2.

According to the structure, the water drop dropped in the groove portion 7 is guided to both ends of the top plate 24, and thereafter guided to bottom ends of the right sidewall 21 and the left sidewall 22 along the let-out groove 8. Therefore, it is possible that the water drop dropped to the right sidewall 21 and/or the left sidewall 22 is prevented from going around to the connector 4.

A let-out groove may be provided on a portion of each of the right sidewall 21 and the left sidewall 22 of the housing 2. The portion is along an extended line L of the rear wall of the dam portion 9.

According to the structure, the water drop dammed by the dam portion 9 is guided to both ends of the top plate 24, and thereafter guided to the bottom end of the right sidewall 21 and the left sidewall 22 along the let-out groove 8. Therefore, it is possible to prevent the water drop dropped to the right sidewall 21 and/or the left sidewall 22 from going around to the connector 4.

The wet inhibition portion may include the top plate 24 which is sloped downward toward an opposite side of the top plate 24 from the connector 4.

According to the structure, it is possible that the water drop falling on the top plate 24 drops downward toward an opposite side of the top plate 24 from the connector 4. Therefore, it is possible that the water drop is prevented from going around to the connector 4.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. An electronic control unit comprising:
a circuit board on which an electronic part is mounted;
a connector mounted on the circuit board, the connector electrically connecting the circuit board with an external equipment; and
a housing defining a storage space for storing the circuit board and a part of the connector, the housing having an opening to expose a tip of the connector to an outside of the housing, wherein
the housing includes a top plate and a wet inhibition portion which prevents a water drop falling on the top plate of the housing from flowing toward the connector.

2. The electronic control unit according to claim 1, wherein
the opening is provided in a first sidewall of the housing.

3. The electronic control unit according to claim 2, wherein
the wet inhibition portion includes a groove portion provided on the top plate.

4. The electronic control unit according to claim 3, wherein
the groove portion entirely extends across the top plate in a width direction of the top plate.

5. The electronic control unit according to claim 2, wherein
the wet inhibition portion includes a dam portion which protrudes upward on the top plate.

6. The electronic control unit according to claim 5, wherein
a top face of the dam portion is sloped downward toward the top plate, the top plate being on an opposite side of the dam portion from the connector.

7. The electronic control unit according to claim 5, wherein
the dam portion is provided on one of edges of the top plate, the one of the edges being nearest to the opening of the top plate among the edges of the top plate.

8. The electronic control unit according to claim 5, wherein
the dam portion entirely extends across the top plate in a width direction of the top plate.

9. The electronic control unit according to claim 5, wherein
the dam portion has a front wall and a rear wall,
the rear wall of the dam portion is farther from the opening of the housing than the front wall of the dam portion is, and
a groove portion is provided on the top plate along the rear wall of the dam portion.

10. The electronic control unit according to claim 9, wherein
the rear wall of the dam portion serves as a sidewall of the groove portion.

11. The electronic control unit according to claim 3 wherein
in addition to the first sidewall of the housing, the housing further has a second sidewall and a third sidewalls opposite to each other,
a bottom of the groove portion is sloped toward one of the second sidewall and the third sidewall of the housing.

12. The electronic control unit according to claim 11, wherein
the bottom of the groove portion is sloped downward toward the second sidewall and the third sidewall of the housing from a substantial center of the groove portion.

13. The electronic control unit according to claim 1, wherein
the top plate is sloped downward toward an opposite side of the top plate from the connector.

14. The electronic control unit according to claim 1, wherein
the housing has the second sidewall and the third sidewall which are opposite to each other, and
the top plate is sloped toward at least one of the second sidewall and the third sidewall of the housing.

15. The electronic control unit according to claim 14, wherein
the top plate includes
a first slope being sloped downward toward one of the second sidewall and the third sidewall from a substantial center of the top plate, and
a second slope being sloped downward toward the other of the second sidewall and the third sidewall from the substantial center of the top plate.

16. The electronic control unit according to claim 4, wherein
in addition to the first sidewall of the housing, the housing further has a second sidewall and a third sidewall opposite to each other, and
a let-out groove connected with the groove portion is provided on each of the second sidewall and the third sidewall of the housing.

17. The electronic control unit according to claim 8, wherein
the dam portion has a front wall and a rear wall,
the rear wall of the dam portion is farther from the opening of the housing than the front wall of the dam portion is,
in addition to the first sidewall of the housing, the housing further has a second sidewall and a third sidewall opposite to each other, and
a let-out groove is provided on a portion of each of the second sidewall and the third sidewall of the housing, the portion being along an extended line of the rear wall of the dam portion.

18. The electronic control unit according to claim 2, wherein
the wet inhibition portion includes the top plate which is sloped downward toward an opposite side of the top plate from the connector.
